(19) United States
(12) Patent Application Publication
(10) Pub. No.: US 2025/0343014 A1
(43) Pub. Date: Nov. 6, 2025

(54) MULTI-FUNCTION BUTTON MODULE, ELECTRONIC DEVICE COMPRISING SAME, AND OPERATING METHOD THEREOF

(71) Applicant: SENSIPIK CO., LTD., Seoul (KR)

(72) Inventor: Seung Hoon KO, Hwaseong-si (KR)

(21) Appl. No.: 19/196,289

(22) Filed: May 1, 2025

(30) Foreign Application Priority Data
May 2, 2024 (KR) 10-2024-0058229

(51) Int. Cl. H01H 13/14; H03K 17/96; H04M 1/72466

(52) U.S. Cl. CPC H01H 13/14; H03K 17/96; H04M 1/72466

(57) ABSTRACT

According to one embodiment, a multi-function button module includes an electrode substrate, a bracket deposed on a lower surface of the electrode substrate, a first adhesive layer deposed on the electrode substrate, a first electrode layer deposed on the first adhesive layer, a second adhesive layer deposed on the first electrode layer, a second electrode layer deposed on the second adhesive layer, a button housing configured to surround the electrode substrate, the first adhesive layer, the first electrode layer, the second adhesive layer, and the second electrode layer, and a pressure sensor layer configured to detect pressure that changes according to an external pressure on the button module.

### CROSS-REFERENCE TO RELATED APPLICATION

This application is based on and claims priority under 35 U.S.C. § 119 to Korean Patent Application No. 10-2024-0058229, filed on May 2, 2024, in the Korean Intellectual Property Office, the disclosure of which is incorporated by reference herein in its entirety.

### BACKGROUND

### 1. Field

The present disclosure relates to a multi-function button module, an electronic device including the multi-function button module, and an operating method of the electronic device, and more specifically, to a multi-function button module that performs operations, such as content selection based on touch pressure and scroll movement, an electronic device including the multi-function button module, and an operating method of the electronic device.

### 2. Description of the Related Art

The basic functions of mobile phones are expanding from calls to video viewing, cameras, games, and so on. Accordingly, the demand for large smartphones, each having a size of 6 inches or more, is increasing compared to the existing small smartphones, each having a size of about 5 inches. Also, due to the recent development of display technology, it is expected that flexible panels of 7 inches or more will be applied to smartphones.

As the functions of mobile phones are expanded and sizes thereof increase, the demand for new user interfaces including back and screen transition functions is increasing.

In order to solve the problem, a navigation bar including back and screen transition functions in the conventional display exists. However, as sizes of smartphones increase, a smartphone user has difficulty in operating a navigation bar of a smartphone with one hand.

Therefore, there is a need for a button module that provides multiple functions such that a user may easily operate an electronic device with one hand through a side button of the electronic device, an electronic device including the button module, and an operating method of the electronic device.
(Patent Document 1) Related Art 1: Korean Patent No. 10-2278725 (Announced on Jul. 13, 2021)
(Patent Document 2) Related Art 2: Korean Patent No. 10-1817527 (Announced on Jan. 5, 2018)

### SUMMARY

The present disclosure provides a multi-function button module that performs operations, such as content selection and scroll movement based on touch pressure, an electronic device including the multi-function button module, and an operating method of the electronic device.

Technical problems to be solved by the present disclosure are not limited to the technical problems described above, and other technical problems of the present disclosure may be derived from the following description.

One embodiment of the present disclosure provides a multi-function button module. The multi-function button module includes an electrode substrate, a bracket deposed on a lower surface of the electrode substrate, a first adhesive layer deposed on the electrode substrate, a first electrode layer deposed on the first adhesive layer, a second adhesive layer deposed on the first electrode layer, and a second electrode layer deposed on the second adhesive layer. Also, the multi-function button module includes a button housing configured to surround the electrode substrate, the first adhesive layer, the first electrode layer, the second adhesive layer, and the second electrode layer, and further includes a pressure sensor layer configured to detect pressure that changes according to an external pressure on the button module.

Also, another embodiment of the present disclosure provides an electronic device including a multi-function button module. The electronic device includes a display, a button module, a main board electrically connected to the button module, at least one processor, and a memory electrically connected to the at least one processor and storing at least one code executed by the at least one processor, and the button module includes an electrode substrate, a bracket deposed on a lower surface of the electrode substrate, a first adhesive layer deposed on the electrode substrate, a first electrode layer deposed on the first adhesive layer, a second adhesive layer deposed on the first electrode layer, and a second electrode layer deposed on the second adhesive layer. Also, the electronic device includes a button housing configured to surround the electrode substrate, the first adhesive layer, the first electrode layer, the second adhesive layer, and the second electrode layer, and further includes a pressure sensor layer configured to detect the type of pressure that changes according to an external pressure on the button module. The bracket includes a plurality of protrusions that come into contact with the pressure sensor layer, and a protrusion adjacent to a position where the external pressure is generated among the plurality of protrusions causes a change in pressure to the pressure sensor layer, depending on positions where the external pressure is generated. Also, the main board includes a haptic motor configured to provide haptic feedback according to pressure detected by the pressure sensor layer, and the memory stores code that causes the at least one processor to determine a type of external pressure detected by the pressure sensor layer.

Also, another embodiment of the present disclosure provides an operating method of an electronic device including a multi-function button module. The operating method includes detecting an external pressure through the button module, determining a type of the external pressure, and performing at least one operation among app content selection, scroll movement, screen switching, camera shooting, camera zoom-in, and camera zoom-out based on the type of the external pressure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a configuration of a multi-function button module according to a embodiment of the present disclosure;

FIG. 2 is a view illustrating the multi-function button module illustrated in FIG. 1 arranged on a side surface of an electronic device;

FIGS. 3 to 5 are diagrams illustrating examples of the multi-function button module illustrated in FIG. 1;

FIG. 6 is a diagram illustrating a configuration of an electronic device including a multi-function button module, according to another embodiment of the present disclosure;

FIG. 7 is a diagram illustrating a configuration of a button module included in the electronic device illustrated in FIG. 6;

FIG. 8 is a diagram illustrating individual components of the electronic device illustrated in FIG. 6 in detail;

FIG. 9 is a diagram illustrating a configuration in which a pressure sensor is arranged within a display rather than a side pressurizing portion of an electronic device;

FIG. 10 is a diagram illustrating in detail a resistance change due to heat generation of an electronic device and a resistance change due to actual pressurization, in a pressure sensor arranged within a display rather than a side pressurizing portion of the electronic device illustrated in FIG. 9;

FIG. 11 is a diagram illustrating a circuit for correcting a change in resistance value due to temperature of the pressure sensor illustrated in FIG. 9;

FIG. 12 is a diagram illustrating a haptic driver circuit including a haptic motor included in the electronic device illustrated in FIG. 6;

FIG. 13 is a diagram illustrating an embodiment of utilizing the electronic device illustrated in FIG. 6 and illustrates in detail a micro-pressure control function for replacing a navigation bar of a smartphone;

FIG. 14 is a diagram illustrating another embodiment of utilizing the electronic device illustrated in FIG. 6 and illustrates in detail a display screen switching function through a scroll gesture;

FIG. 15 is a view illustrating another embodiment of utilizing the electronic device illustrated in FIG. 6 and illustrates in detail a quick menu pop-up function;

FIG. 16 is a flowchart illustrating a sequence of an operating method of an electronic device including a multi-function button module, according to another embodiment of the present disclosure; and

FIGS. 17 to 19 are flowcharts illustrating an operating method sequence of embodiments of a multi-function providing operation among operating methods illustrated in FIG. 16.

FIG. 20 is a diagram illustrating another example in which the button module illustrated in FIGS. 1 and 7 is implemented.

FIGS. 21 and 22 are diagrams illustrating that different functions are performed according to pressure levels applied to the button module illustrated in FIGS. 1 and 7.

FIGS. 23 to 27 are diagrams illustrating another embodiment utilizing the electronic device illustrated in FIG. 6.

### DETAILED DESCRIPTION

Hereafter, the present disclosure will be described in detail with reference to the accompanying drawings. However, the present disclosure may be implemented in many different forms and is not limited to the embodiments described herein. Also, the accompanying drawings are only for easy understanding of the embodiments disclosed in the present specification, and the technical ideas disclosed in the present specification are not limited by the accompanying drawings. All terms, which include technical and scientific terms used herein, should be interpreted as having the meaning generally understood by a person of ordinary skill in the art to which the present disclosure belongs. Terms defined in advance should be interpreted as having additional meanings consistent with the relevant technical literature and the present disclosure, and should not be interpreted in a very ideal or restrictive sense unless otherwise defined.

In order to clearly describe the present disclosure in the drawings, parts irrelevant to the descriptions are omitted, and a size, a shape, and a form of each component illustrated in the drawings may be variously modified. The same or similar reference numerals are assigned to the same or similar portions throughout the specification.

Suffixes “module”, “layer”, “portion”, and “unit” for the components used in the following description are given or used interchangeably in consideration of ease of writing the specification, and do not have meanings or roles that are distinguished from each other by themselves. Also, in describing the embodiments disclosed in the present specification, when it is determined that a detailed descriptions of related known technologies may obscure the gist of the embodiments disclosed in the present specification, the detailed descriptions are omitted.

Throughout the specification, when a portion is said to be “connected (coupled, in contact with, or combined)” with another portion, this includes not only a case where it is “directly connected (coupled, in contact with, or combined)”, but also a case where there is another member therebetween. Also, when a portion “includes (comprises or provides)” a certain component, this does not exclude other components, and means to “include (comprise or provide)” other components unless otherwise described.

Terms indicating ordinal numbers, such as first and second, used in the present specification are used only for the purpose of distinguishing one component from another component and do not limit the order or relationship of the components. For example, the first component of the present disclosure may be referred to as the second component, and similarly, the second element may also be referred to as the first component. As used herein, singular forms should be construed to include plural forms as well, unless the opposite is clearly indicated.

A “memory” described below may store at least one of information and data input to a communication module, information and data required for functions performed by a processor, and data generated according to the execution of the processor. Also, the memory should be interpreted as a general term indicating a nonvolatile storage device that maintains the stored information even when power is not supplied and a volatile storage device that requires power to maintain the stored information. A “memory” may perform a function of temporarily or permanently storing data, and may include magnetic storage media or flash storage media in addition to a volatile storage device that requires power to maintain the stored information, but the scope of the present disclosure is not limited thereto. A “processor” may include various types of devices that control and process data. The “processor” may indicate a data processing device which includes a physically structured circuit to perform a function expressed as code or command included in a program and is built in hardware. For example, the processor may be implemented with a microprocessor, a central processing unit (CPU), a processor core, a multiprocessor, an application-specific integrated circuit (ASIC), a field programmable gate array (FPGA), or so on, but the scope of the present disclosure is not limited thereto.

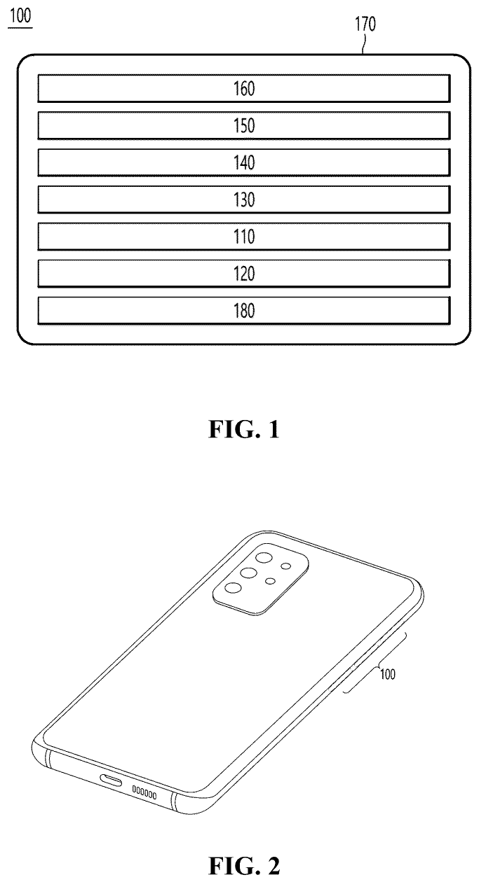

FIG. 1 is a diagram illustrating an example of a configuration of a multi-function button module 100 according to an embodiment of the present disclosure. Hereinafter, the multi-function button module 100 is described in detail with reference to FIG. 1.

Referring to FIG. 1, a multi-function button module 100 according to an embodiment of the present disclosure includes an electrode substrate 110, a bracket 120 on a lower surface of the electrode substrate 110, a first adhesive layer 130 on the electrode substrate 110, a first electrode layer 140 on the first adhesive layer 130, a second adhesive layer 150 on the first electrode layer 140, a second electrode layer 160 on the second adhesive layer 150, and a button housing 170.

The button module 100 may further include a pressure sensor layer 180 that detects pressure for changing according to an external pressure on the button module 100 and measures a change in resistance. The bracket 120 includes a plurality of protrusions and generates pressure on a certain region of the pressure sensor layer 180 according to external pressure, and the first adhesive layer 130 may include an elastic body. Also, depending on manufacturing processes, the first adhesive layer 130 may be omitted, and the first electrode layer 140 may be included in a printed structure on the electrode substrate 110. Also, the pressure sensor layer 180 may be deposed on a lower surface of the bracket 120 or between the electrode substrate 110 and the first adhesive layer 130, and may include a plurality of resistance elements and may detect pressure according to a change in resistance by using the resistance elements. Also, the electrode substrate 110 may include a haptic motor for haptic feedback.

The first electrode layer 140 may include one or more reception electrodes, and the second electrode layer 160 may include a plurality of drive electrodes. Also, the first electrode layer 140 and the second electrode layer 160 may operate as a capacitive touch sensor made of a conductor, and capacitive capacitance is generated between the first electrode layer 140 and the second electrode layer 160. The multi-function button module 100 may have a multi-layer touch electrode structure in which the first electrode layer 140 includes one or more reception channels and the second electrode layer 160 includes a plurality of drive electrodes, and may measure a capacitance change according to a scroll position. Also, when the second adhesive layer 150 is composed of an elastic body, the capacitance between the first electrode layer 140 and the second electrode layer 160 changes according to pressure, and accordingly, pressure change may be detected without a separate pressure sensor layer 180. Also, the pressure sensor layer 180 may detect the pressure that changes according to an external pressure on the button module 100.

Referring to FIGS. 1 and 2 together, the multi-function button module 100 may replace an existing physical button and be placed on a side surface of an electronic device, and a size and thickness thereof may be equal to a size and thickness of the existing physical button. Also, the multi-function button module 100 may be placed on an opposite side of the existing physical button while leaving the existing physical button as it is, and may perform an additional function. Alternatively, the button module 100 may be embedded inside the device instead of being externally exposed, enabling a seamless unibody smartphone design without physical buttons.

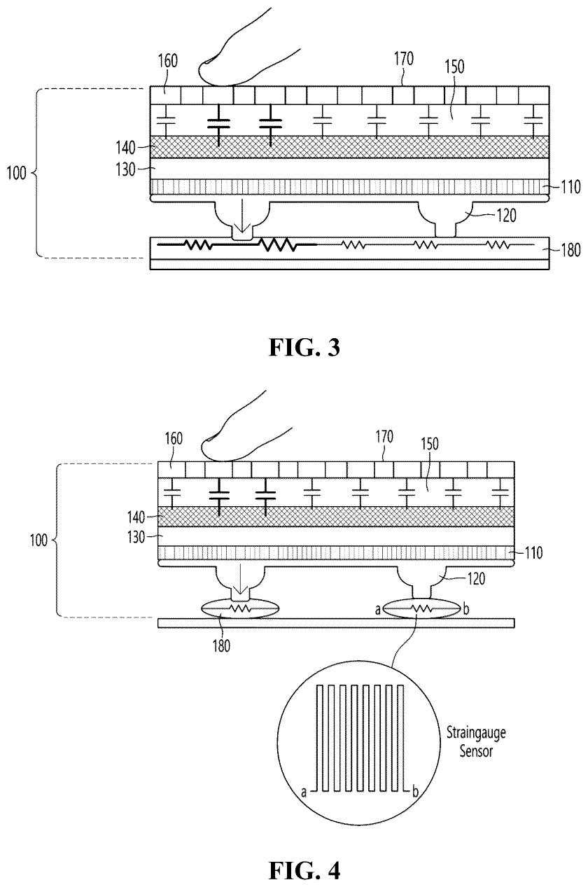

FIGS. 3 and 4 are diagrams illustrating the pressure sensor layer 180 deposed on a lower portion of the bracket 120 as an embodiment of the multi-function button module 100. The pressure sensor layer 180 includes a plurality of resistance elements, and may detect pressure according to a change in resistance by using the plurality of resistance elements. The bracket 120 includes a plurality of protrusions that come into contact with the pressure sensor layer 180, and depending on positions where an external pressure is generated, a protrusion adjacent to a position where the external pressure is generated among protrusions causes a change in pressure to the pressure sensor layer 180. Also, the pressure sensor layer 180 may be composed of one layer, and an independent pressure sensor may be deposed at a pressurized point of the bracket 120, but the scope of the present disclosure is not limited thereto.

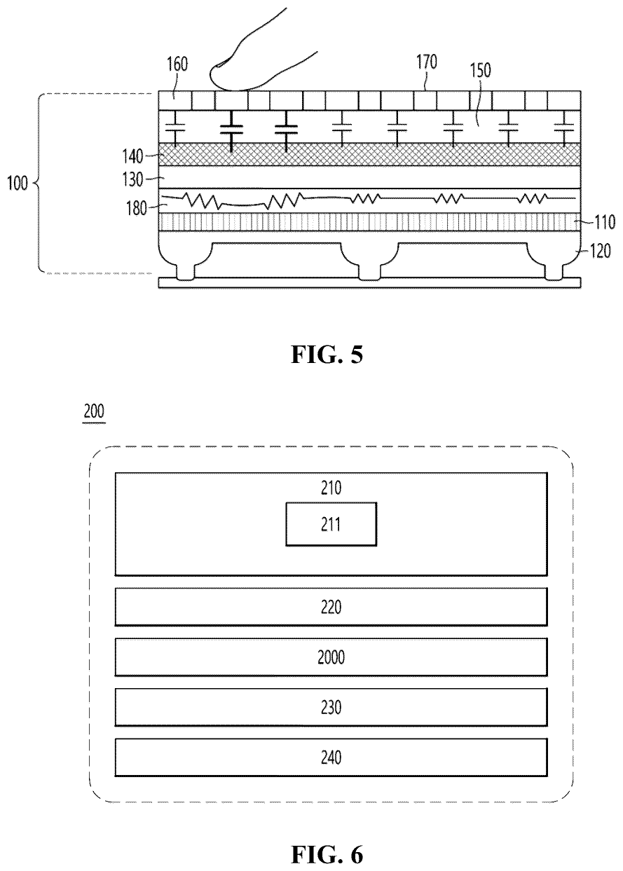

FIG. 5 is a diagram illustrating the pressure sensor layer 180 arranged between the electrode substrate 110 and the first adhesive layer 130 as another embodiment of the multi-function button module 100. In this case, a change in density of an elastic body included in the first adhesive layer 130 may cause a change in pressure for the pressure sensor layer 180.

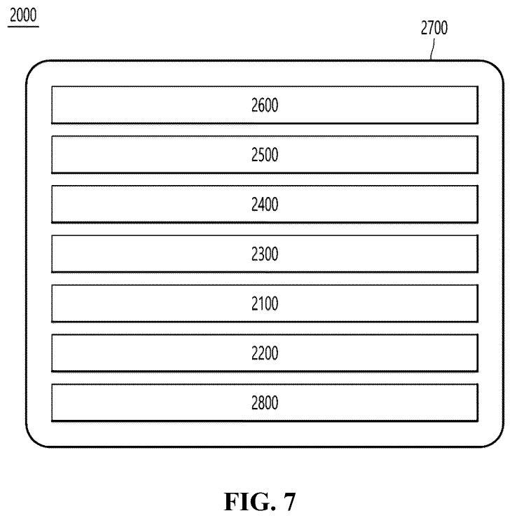

FIG. 6 is a diagram illustrating an example of a configuration of an electronic device 200 including a button module 2000 according to another embodiment of the present disclosure, and FIG. 7 is a diagram illustrating an example of a configuration of the button module 2000 included in the electronic device 200. Also, the button module 2000 included in the electronic device 200 is substantially the same the multi-function button module 100.

Referring to FIG. 6, the electronic device 200 includes a main board 210, a display 220, a button module 2000, a processor 230, and a memory 240. The main board 210 is electrically connected to the button module 2000 and includes a haptic motor 211 that provides haptic feedback according to the pressure detected by the pressure sensor layer 2800. The haptic motor may be mounted not only on the main board 210 but also within the button module 2000, enabling localized haptic feedback near the user's touch and pressure. Also, the memory 240 is electrically connected to the processor 230 and stores at least one code executed by the processor 230 and code that causes the processor 230 to determine the type of external pressure detected by the pressure sensor layer 2800. The memory 240 stores code that causes the at least one processor to measure a change in capacitance generated between the first electrode layer and the second electrode layer.

Referring to FIG. 7, the button module 2000 included in the electronic device 200 includes an electrode substrate 2100, a bracket 2200, a first adhesive layer 2300 on the electrode substrate 2100, a first electrode layer 2400 on the first adhesive layer 2300, a second adhesive layer 2500 on the first electrode layer 2400, and a second electrode layer 2600 on the second adhesive layer 2500. Also, the button module 2000 includes a button housing 2700 configured to surround the first adhesive layer 2300, the first electrode layer 2400, the second adhesive layer 2500, and the second electrode layer 2600, and further includes the pressure sensor layer 2800 which detects the type of pressure that changes according to an external pressure on the button module 2000. In this case, the first electrode layer 2400 and the second electrode layer 2600 may operate as a capacitive touch sensor made of a conductor, and capacitance is generated between the first electrode layer 2400 and the second electrode layer 2600. Also, the bracket 2200 includes a plurality of protrusions that come into contact with the pressure sensor layer 2800, and depending on positions where the external pressure is generated, the protrusion adjacent to a position where the external pressure is generated among the plurality of protrusions causes a pressure change to the pressure sensor layer.

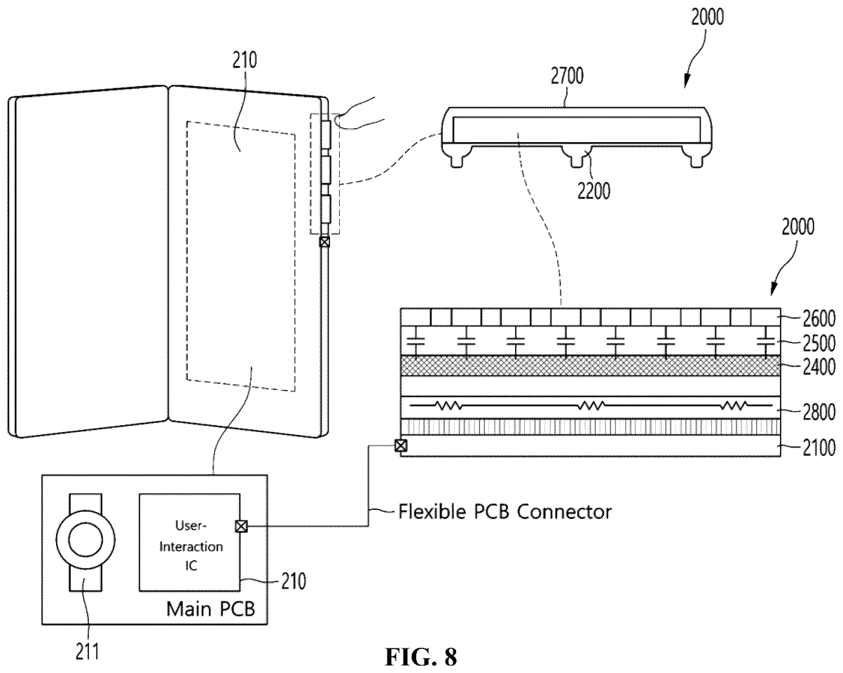

Referring to FIG. 8, the button module 2000 and the haptic motor 211 may be deposed in the same space, and a haptic driver including the haptic motor 211 and a sensor circuit of the button module 2000 may be implemented as a single chip to obtain a mounting space and mass production. Also, the haptic motor 211 may be placed on the main board 210 and placed close to a side button to optimize the click feeling of a button. Also, by considering strength, a provision position, and so on of the haptic, the haptic motor 211 may be placed on the electrode board 2100 of the button module 2000, but the scope of the present disclosure is not limited thereto. The sensor circuit may also be mounted on the electrode board 2100 of the button module 2000, and may be integrally implemented with the button module 2000 as a single module or package. Also, the button module 2000 may be configured to be embedded inside the electronic device, excluding the housing, such that no portion of the button module protrudes outside the device, thereby enabling a seamless external design.

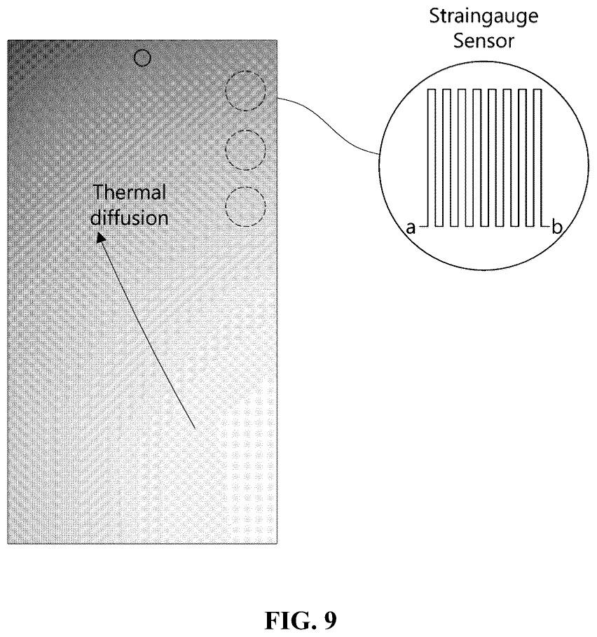

FIG. 9 is a diagram illustrating in detail a configuration in which a pressure sensor is deposed in the display, not a side pressurizing portion of the electronic device 200.

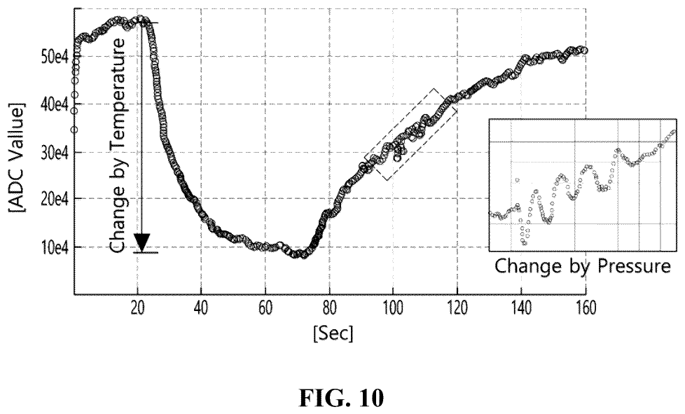

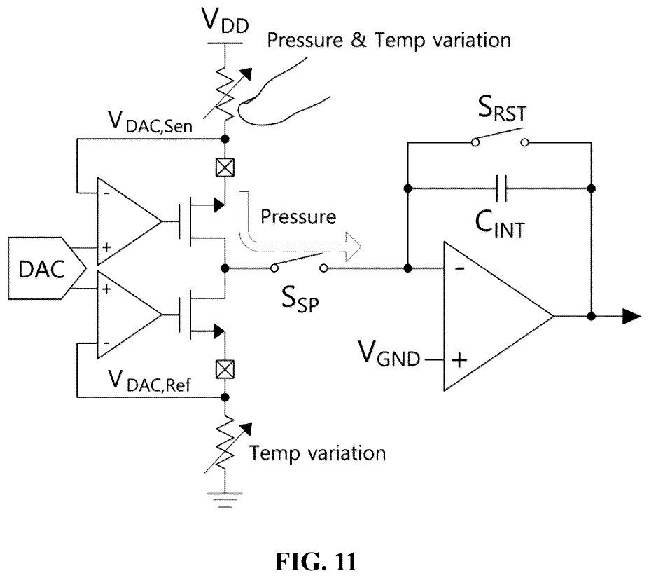

Referring to FIGS. 9 to 11, the electronic device 200 may include the pressure sensor in the display, not the pressurizing portion, and may measure only a resistance change due to actual pressurization through a differential detection circuit illustrated in FIG. 11. More specifically, when the pressure sensor is deposed in the display, a resistance change of the pressure sensor due to the heat generation of the electronic device 200 occurs more than a resistance change due to actual pressurization, and accordingly, by removing subtracting the resistance change by using the differential detection circuit illustrated in FIG. 11, only the resistance change due to pressurization may be measured. Through the resistance change measurement, it is possible to determine whether actual external pressure is applied or not. Also, the differential detection circuit of FIG. 11 may be used not only when the pressure sensor is deposed in the display, but also when the pressure sensor is deposed on a side surface of the electronic device 200.

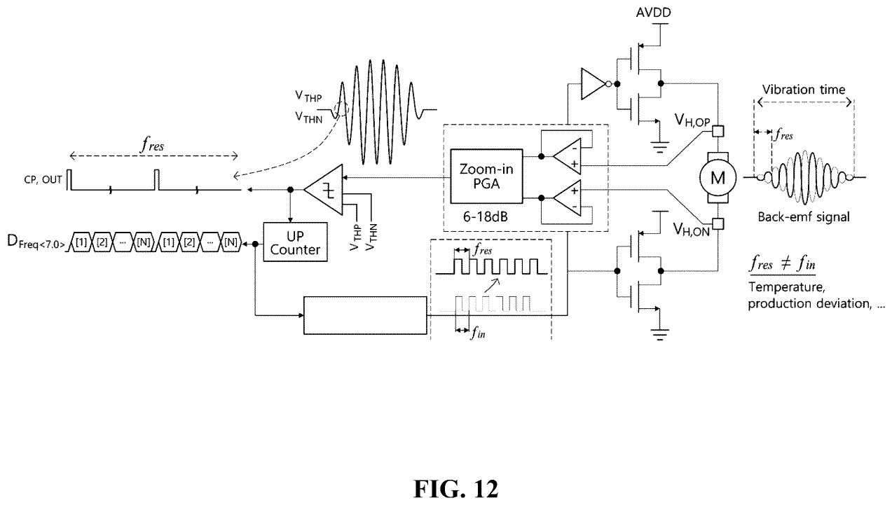

Referring to FIG. 12, a haptic driver including the haptic motor 211 may maximize the motor vibration intensity by matching a drive frequency of a motor to a natural frequency thereof, and accordingly, sophisticated haptic feedback may be provided. More specifically, a motor's motion waveform is amplified by a programmable gain amplifier (hereinafter, PGA) and the motor's natural frequency is measured by measuring a zero crossing point of a waveform. When a drive frequency input to a motor is different from a natural frequency of the motor, the drive frequency is matched to the natural frequency, and the motor vibration intensity is maximized to provide sophisticated haptic feedback. Also, the haptic driver including the haptic motor 211 may provide a separate storage space for storing a haptic pattern.

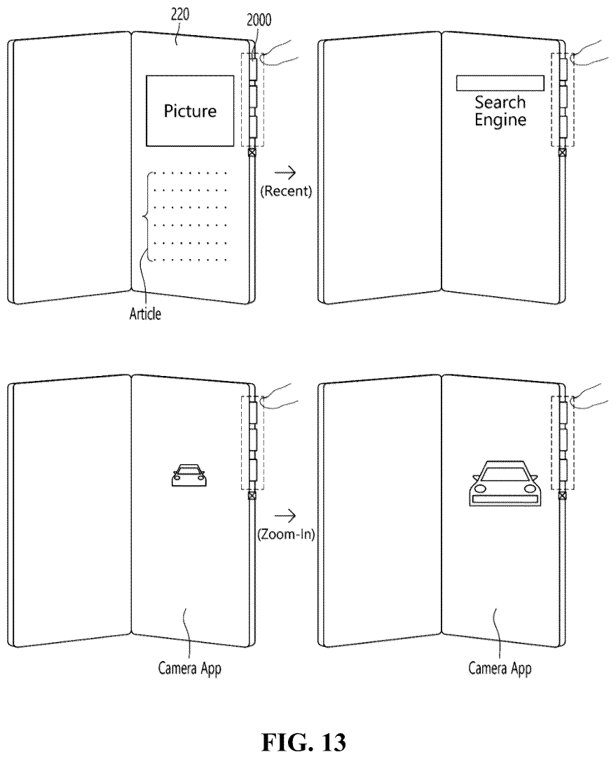

FIG. 13 is a diagram illustrating a micro-pressure control function according to an embodiment utilizing the electronic device 200 including the button module 2000. A physical button of an existing device may be replaced with the multi-function button module 2000, and therethrough, an existing navigation bar may be replaced, allowing a display of a mobile phone to be conveniently operated with one hand. More specifically, depending on contents used by a user, a power button (Pw) function included in the existing physical buttons may be replaced with a home or camera shooting function, a volume down (Vdn) function may be replaced with a back or camera zoom-in function, and a volume up (Vup) function may be replaced with a forward (Recent) or camera zoom-out function, but the scope of the present disclosure is not limited thereto. Furthermore, the button module 2000 may support a multi-level pressure detection function, whereby different functions may be executed according to the magnitude of the external pressure applied. For example, a light press may trigger a home function, a medium press may trigger a camera shooting function, and a strong press may trigger a power off function. This pressure-based functional mapping enables diverse input methods using a single button area, thereby improving user convenience and interface flexibility.

The number of detectable pressure levels is not limited to three and may be further subdivided to support additional functions. Moreover, the function assigned to each pressure level may be dynamically adjusted based on the type of application running or user preferences, allowing context-aware and customizable interaction schemes.

TABLE 1

| | Pressure | Pressure Level 2 | |
|---|---|---|---|
| | Level 1 | Internet App | Camera App |
| Button 1 | Power On/Off | Home | Shot |
| Button 2 | Volumn Down | Back | Zoom-In |
| Button 3 | Column Up | Recent | Zoom-Out |

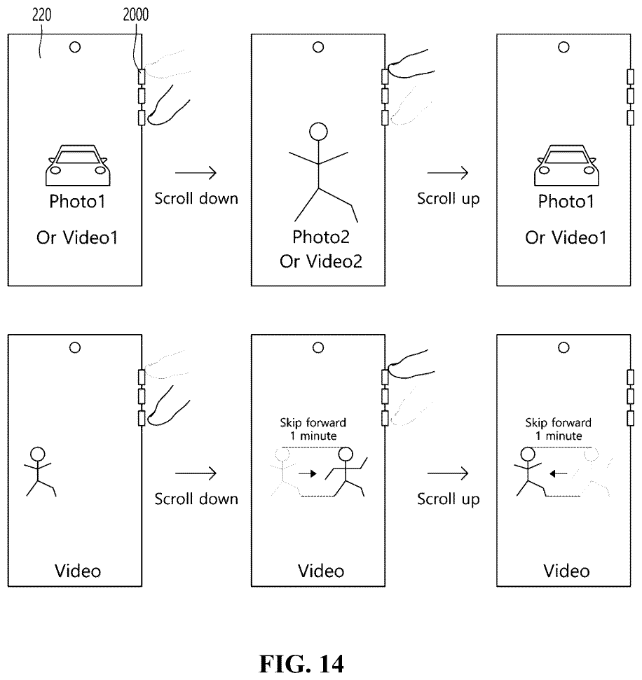

FIG. 14 is a diagram illustrating another embodiment of an electronic device 200 including a button module 2000 and illustrates a screen switching function through a scroll gesture. A scroll operation may be performed by using a capacitance change between the first electrode layer 2400 and the second electrode layer 2600 or a resistance change due to pressure. In this case, a scroll down operation may be performed when a finger moves from an upper portion of the button module 2000 to a lower portion the button module 2000, and a scroll up operation may be performed when a finger moves from the lower portion to the upper portion. Also, a stop or play operation of a video being watched may be performed by applying pressure to the button module, but the scope of the present disclosure is not limited thereto. Furthermore, not only stop or play operations of a video being watched, but also fast-forward and rewind operations may be performed through pressure input or scrolling gestures applied to the button module 2000.

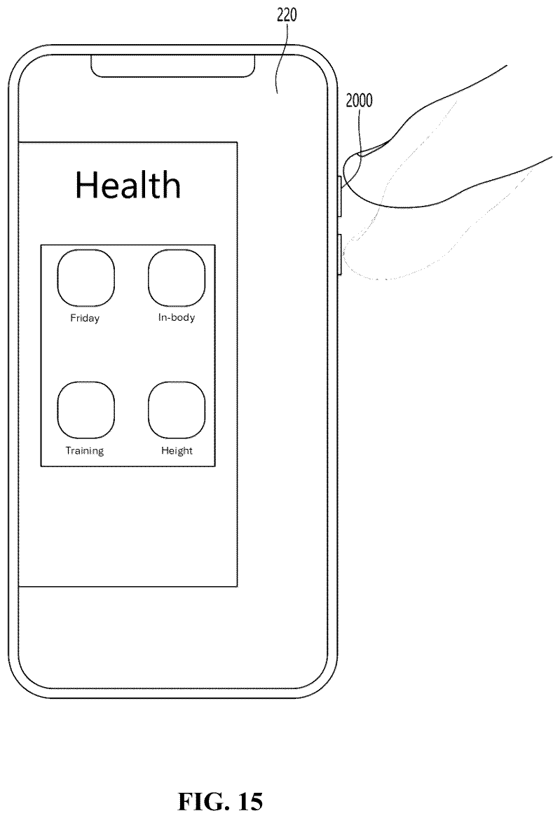

FIG. 15 is a view illustrating a quick menu pop-up function according to another embodiment of the electronic device 200 including a button module 2000. When the scroll function using the capacitance change between the first electrode layer 2400 and the second electrode layer 2600 or the resistance change due to pressure is activated, the preset quick menu pop-up is activated, and a desired icon may be selected through a pressure input. In this case, a quick menu may include a list of apps preset by a user, or a list of apps recommended by the processor 230 of the electronic device 200, but the scope of the present disclosure is not limited thereto. Alternatively, when a soft pressure is applied to the button module 2000 as part of the multi-level pressure input, a quick menu pop-up may be triggered instead of executing a conventional function such as volume control or power button operation. In such a case, the user may select a desired icon from the popped-up quick menu by performing a scrolling gesture on the button module 2000.

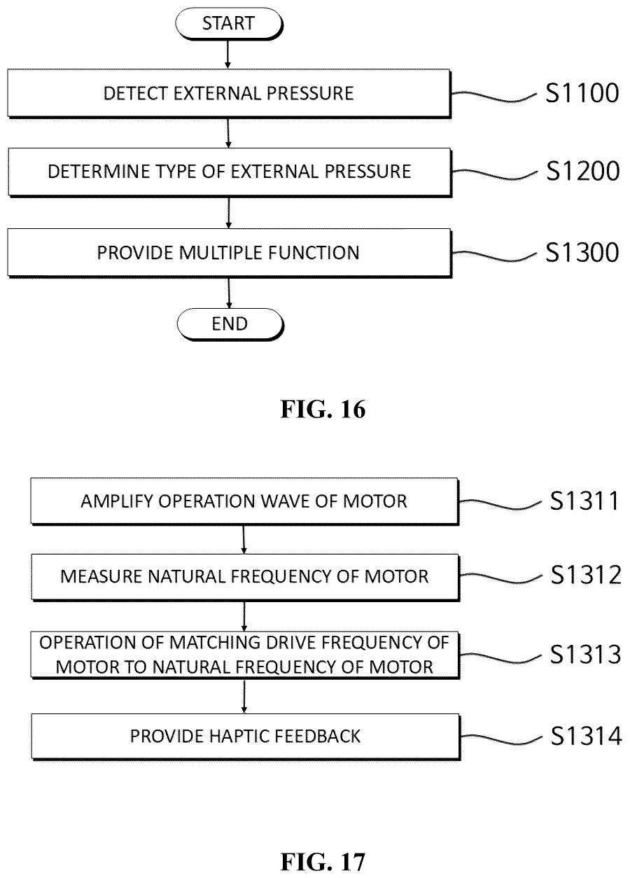

FIG. 16 is an operation flowchart illustrating an operating method of the electronic device 200 according to another embodiment of the present disclosure, and FIGS. 16 to 18 are flowcharts illustrating detailed operations included in some operations of the operating method of the electronic device 200. Hereinafter, the operating method of the electronic device 200 will be described with reference to FIGS. 16 to 19. Each operation of the operating method of the electronic device 200 described below may be performed by the electronic device 200 including the multi-function button module 100 and button module 2000 described above with reference to FIGS. 1 to 15. Therefore, the embodiments of the present disclosure described above with reference to FIGS. 1 to 15 may be equally applied to the embodiments described below, and redundant descriptions thereof are omitted. The operations described below do not have to be performed sequentially, and the order of the operations may be set in various ways, and the operations may be performed almost simultaneously.

Referring to FIG. 16, an operating method of the electronic device 200 including the button module 2000 is performed by a processor, and includes operation S1100 of detecting an external pressure, operation S1200 of determining the type of external pressure, and operation S1300 of providing multiple functions.

Operation S1100 of detecting an external pressure is an operation of detecting the external pressure provided to the outside of the button module 2000. Operation S1100 is an operation of detecting a pressure change caused by the external pressure to the pressure sensor layer 2800. More specifically, pressure is detected according to a resistance change of a plurality of resistance elements included in the pressure sensor layer 2800. Also, the external pressure may be generated by a density change of an elastic body included in the bracket 2200 or the first adhesive layer 2300 of the button module 2000. Operation S1100 may comprise detecting a change in capacitance through the button module.

Operation S1200 of determining the type of external pressure is an operation of determining the type of the external pressure after pressure is detected. In this case, the type of external pressure may include a case where the external pressure moves from the top to the bottom of the button module 2000, a case where the pressure moves from the bottom to the top, a case where the pressure is applied once, a case where the pressure is a long-lasting pressure, a case where the pressure is applied multiple times, or a case where the pressure is greater than or equal to or less than a certain threshold, but the scope of the present disclosure is not limited thereto. Operation S1200 may comprise determining a type of the change in the capacitance.

Referring to FIGS. 17 to 19, operation S1300 of providing the multiple functions includes operation S1300 of providing haptic feedback, operation S1320 of performing an app content selection, a scroll movement, and a screen switching operation, and operation S1330 of performing a camera zoom and a shooting operation.

Referring to FIG. 17, operation S1300 of providing the haptic feedback includes operation S1311 of amplifying an operation waveform of a motor, operation S1312 of measuring a natural frequency of the motor, and operation S1313 of matching the drive frequency of the motor to the natural frequency thereof.

Operation D1311 of amplifying the operation waveform of the motor is an operation of amplifying the operation waveform of the motor by using a PGA. Operation S1312 of measuring the natural frequency of the motor is an operation of measuring the natural frequency of the motor by measuring a zero crossing point of the waveform amplified by the PGA. Operation S1313 of matching the drive frequency of the motor to the natural frequency thereof is an operation of maximizing vibration intensity of the motor by matching the drive frequency of the motor to the natural frequency thereof by using a microcontroller (hereinafter, an MCU) when the drive frequency is different from the natural frequency, and thereby, haptic feedback may be provided.

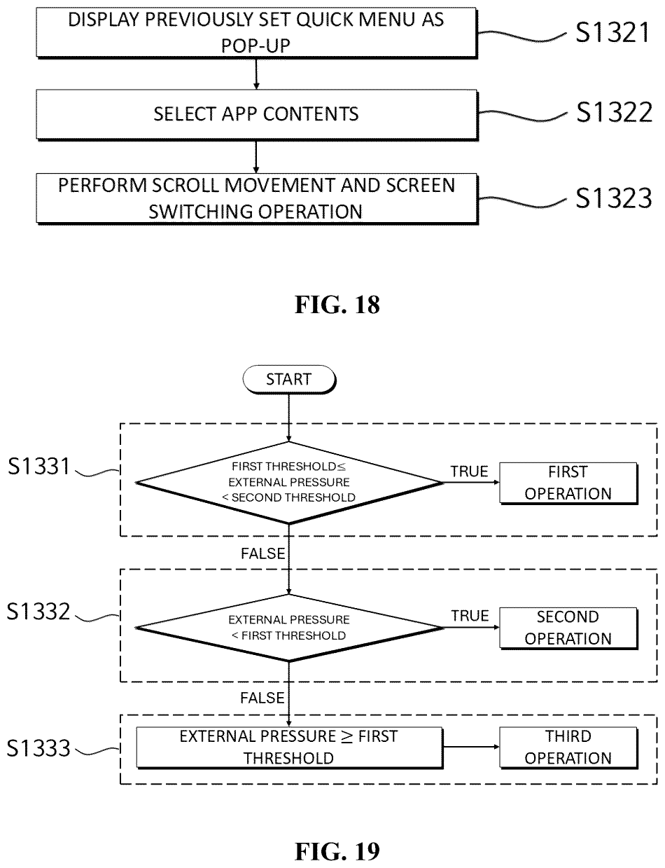

Referring to FIG. 18, operation S1320 of performing app content selection, scroll movement, and screen switching operation includes operation S1321 of displaying a preset menu as a pop-up, operation S1322 of selecting a desired app, and operation S1323 of performing scroll movement or screen switching operation according to a selected app.

Operation S1321 of displaying a preset quick menu as a pop-up is an operation of displaying a corresponding quick menu on the display 220 when a user presets a desired app in the quick menu. The quick menu may include at least one app, and may include an operation of displaying a recommended app on the display 220 when there is no preset quick menu. Operation S1322 of selecting a desired app is an operation of selecting one of quick menus displayed on the display 220. Operation S1323 of performing a scroll movement or screen switching operation is an operation of activating a screen switching or scroll function according to the app selected by a user and performing a function when the button module 2000 is touched by a finger. More specifically, when an external pressure by a finger moves from the top to the bottom of the button module 2000, a scroll down function is performed, and when the pressure moves from the bottom to the top, a scroll up function is performed. Also, the scroll function may also be performed by a touch sensor that measures a capacitance change between the first electrode layer 2400 and the second electrode layer 2600 rather than an up-and-down movement of the external pressure. Also, one or more operations of screen switching or up-and-down scrolling may be performed according to the selected app, but the scope of the present disclosure is not limited thereto.

Referring to FIG. 19, operation S1330 of performing a camera zoom and a shooting operation includes operation S1331 of performing a first operation when an external pressure or the change in the capacitance is equal to or greater than a first threshold and less than a second threshold, operation S1332 of performing a second operation different from the first operation when the external pressure or the change in the capacitance is less than the first threshold, and operation S1333 of performing a third operation when the external pressure or the change in the capacitance is equal to or greater than the second threshold. The first threshold and the second threshold are set by the electronic device 200 itself or may be set by a user to any value, and the second threshold should be interpreted as a value greater than the first threshold. Also, the first to third operations should be interpreted as different operations. The first to third operations may include one of camera zoom-in, camera zoom-out, and a shooting function, but the scope of the present disclosure is not limited thereto.

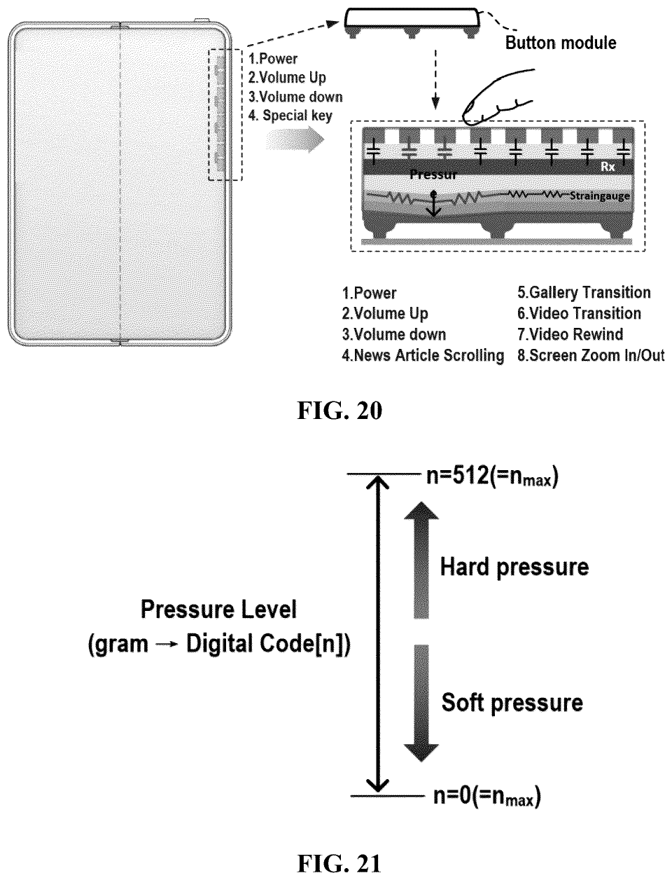

Referring to FIG. 20, the button module 100 shown in FIG. 1 and the button module 2000 shown in FIG. 7 may be embedded in the side frame of the electronic device 200 or disposed on the outside of the side frame. The button modules 100, 2000 may be configured to perform not only Power and Volume up/down functions but also user-defined actions. In the case of performing user-defined actions, the button may be referred to as a “Special Key Button” as illustrated in FIG. 20. The user-defined actions may include operations such as news article scrolling, gallery transition, video transition, video rewind, and screen zoom in/out.

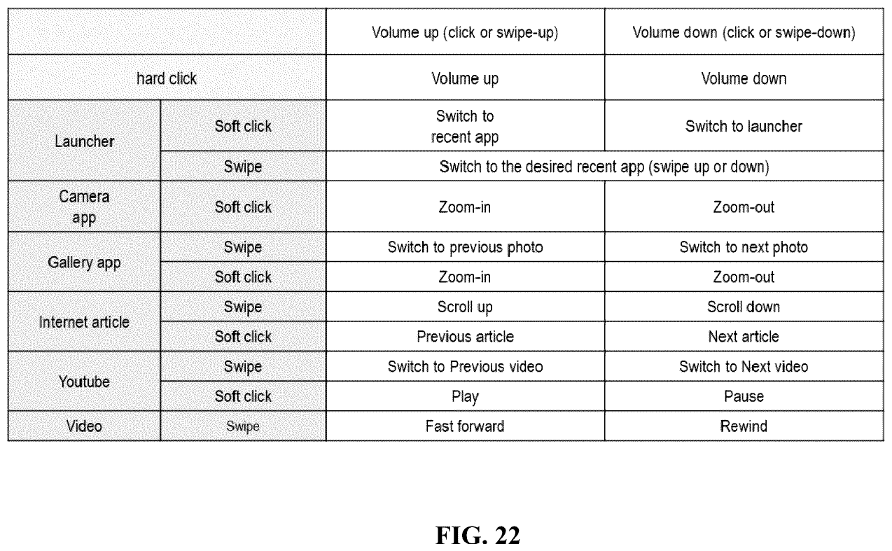

FIGS. 21 and 22 are diagrams illustrating that different functions are performed depending on the pressure levels applied to the button module illustrated in FIGS. 1 and 7.

Referring to FIG. 21, the pressure applied to the button modules 100, 2000 may be classified into hard pressure (click) and soft pressure (click) depending on the level. The button modules 100, 2000 read the applied pressure in grams as a digital code (n), where n_max (=512) and n_min (=0) may be set. However, the values of 512 and 0 are merely examples, and various combinations of digital codes and gram values may be possible.

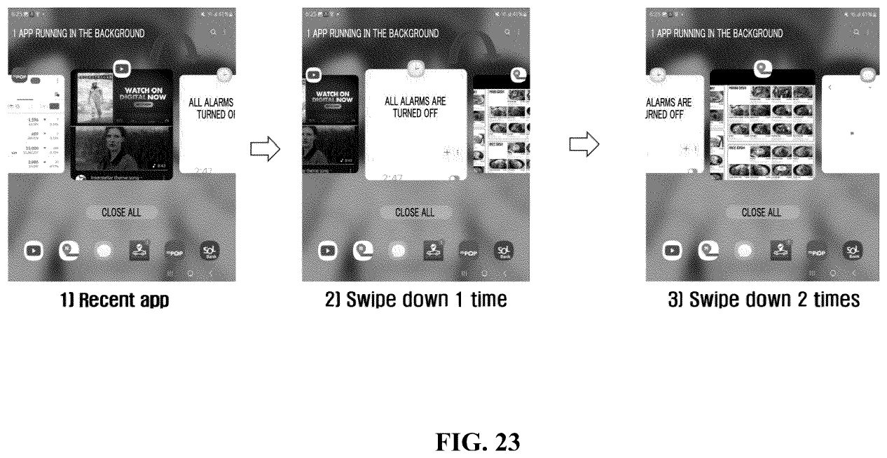

Referring to FIG. 22, different functions are performed in a launcher, camera app, gallery app, internet article screen, YouTube, and video playback depending on the pressure level applied to the button modules 100, 2000. The functions illustrated in FIG. 22 are not limited thereto and may include more diverse functions. Each of the functions shown in FIG. 22 will be described with reference to FIGS. 23 to 27.

FIG. 23 is a diagram illustrating a function performed in the launcher screen by the button modules 100, 2000.

Referring to FIG. 23, when the user performs a soft click input using the button modules 100, 2000, the electronic device (200) displays a recent app screen showing recently used applications. If the user then performs a swipe down gesture once, the device updates the application list and displays the next set of apps. An additional swipe down gesture prioritizes the most recently used applications. Through this process, an intuitive recent app navigation experience can be provided with simple button input.

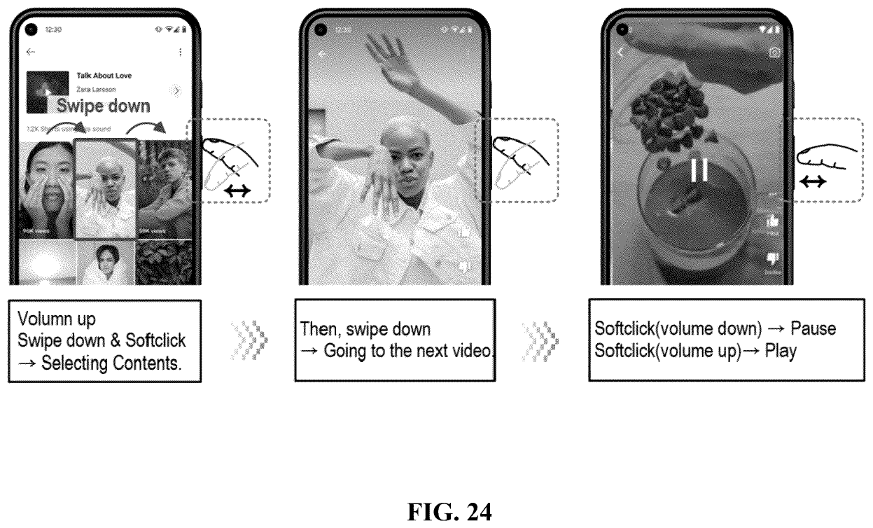

FIG. 24 is a diagram illustrating a function performed on a YouTube app screen by the button modules 100, 2000.

Referring to FIG. 24, the user may perform a swipe gesture in the thumbnail area to select a desired video in the YouTube app, and soft click the volume up button to play the selected video. While the video is playing, the user may perform swipe up or swipe down gestures to move to the next or previous video. The user may also soft click the volume down button to pause the video or soft click the volume up button to resume playback. As such, the button module enables video selection, playback, pause, and transition operations with a single button, enhancing user experience and improving usability and intuitiveness.

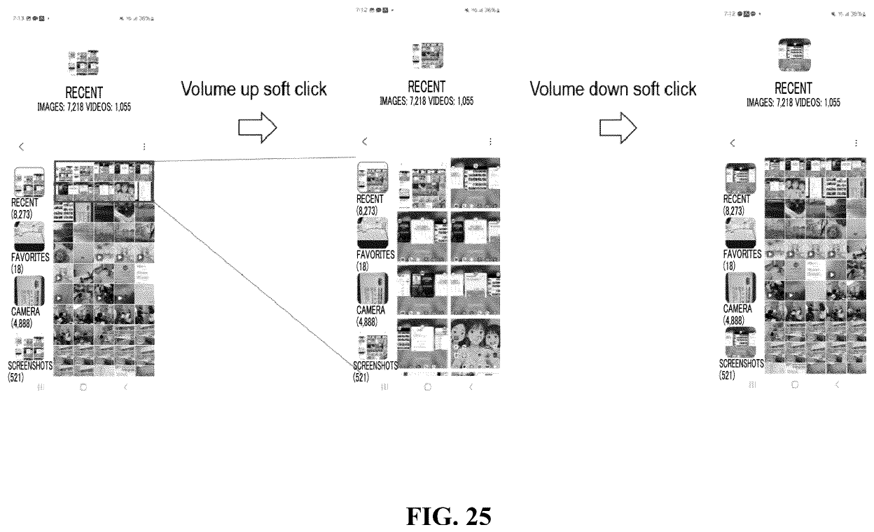

FIG. 25 is a diagram illustrating a function performed in a gallery app by the button modules 100, 2000.

Referring to FIG. 25, the user may perform a swipe gesture to navigate the photo list in the gallery app and soft click the volume up button to select a desired photo. This photo selection method may be implemented similarly to the recent app selection in FIG. 23 or the YouTube video selection in FIG. 24. The selected photo may be enlarged (zoomed in) with a soft click on the volume up button and reduced (zoomed out) with a soft click on the volume down button to return to the previous screen. Thus, intuitive and efficient content browsing and selection in the gallery can be achieved with simple button inputs.

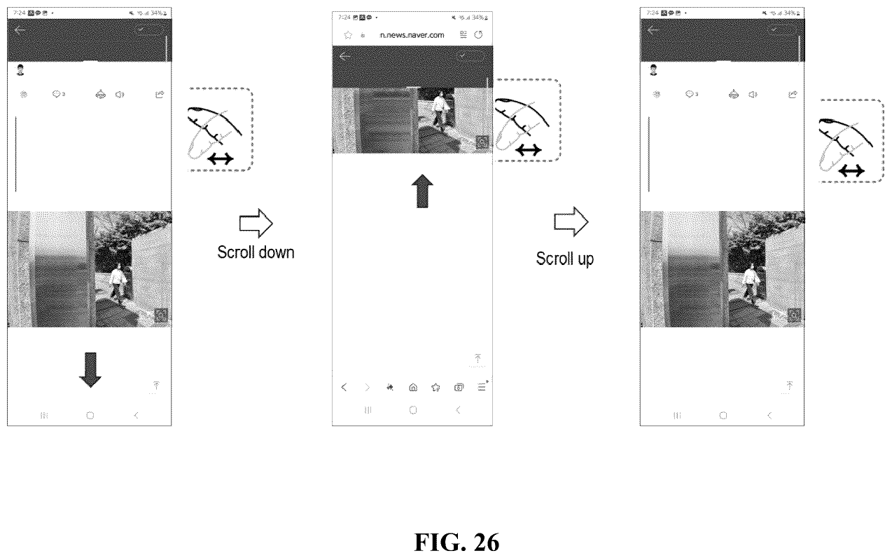

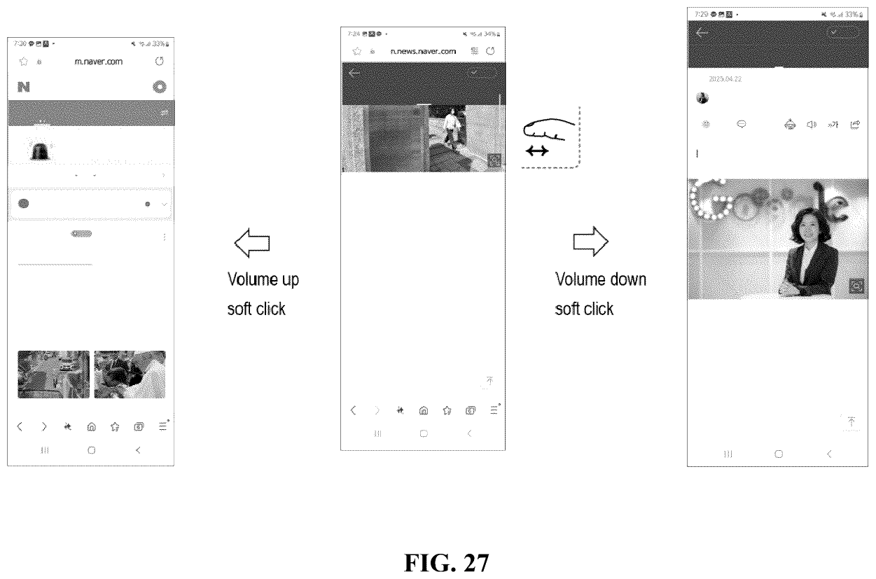

FIGS. 26 and 27 are diagrams illustrating functions performed on an internet article screen by the button modules 100, 2000.

Referring to FIG. 26, when the user is reading a news article or other internet content, the screen may be scrolled vertically using the button module 2000. Specifically, a swipe down gesture may scroll down the current article to read the lower portion, and a swipe up gesture may scroll back to the upper portion of the same article. In some cases, a prolonged swipe or additional gesture may allow navigation to the next or previous article.

Referring to FIG. 27, when the user is on the article list screen of an internet article app, a soft click on the volume down button moves to the full content view of the selected article. Conversely, in the full content view, a soft click on the volume down button transitions to the next article written after the current one, while a soft click on the volume up button returns to the previous article or to the article list screen. These operations allow article navigation solely through soft inputs of the button modules 100, 2000, enabling efficient content browsing without touch gestures and providing an intuitive button-based news reading environment.

According to the present disclosure described above, multiple functions including volume control, back, home, and screen switching may be used with one hand depending on apps being executed through pressure detection.

Also, camera zoom-in/zoom-out and a photo shooting function may be provided depending on the degree of pressure on a button.

Also, up/down/left/right scroll gestures may be recognized to switch the video being watched or scroll newspaper articles and so on up and down without a screen touch operation.

Also, when a scroll function is activated, a function of activating a quick menu set previously by a user as a pop-up may be provided.

Also, an icon of the quick menu activated through a pressure input may be selected.

Effects of the present disclosure are not limited to the effects described above, and include all effects understood from the descriptions.

those skilled in the art to which the present disclosure belongs will understand that the present disclosure may be easily modified into another specific form based on the descriptions given above without changing the technical idea or essential features of the present disclosure. Therefore, the embodiments described above should be understood as illustrative in all respects and not limiting. The scope of the present disclosure is indicated by the claims described below, and all changes or modified forms derived from the meaning, scope of the claims, and their equivalent concepts should be interpreted as being included in the scope of the present disclosure. The scope of the present application is indicated by the claims described below rather than the detailed description above, and all changes or modified forms derived from the meaning, scope of the claims, and their equivalent concepts should be interpreted as being included in the scope of the present application.

What is claimed is:

1. a button module comprising:
an electrode substrate;
a bracket deposed on a lower surface of the electrode substrate;
a first adhesive layer deposed on the electrode substrate;
a first electrode layer deposed on the first adhesive layer;
a second adhesive layer deposed on the first electrode layer;
a second electrode layer deposed on the second adhesive layer;
a button housing configured to surround the electrode substrate, the first adhesive layer, the first electrode layer, the second adhesive layer, and the second electrode layer; and
a pressure sensor layer configured to detect pressure that changes according to an external pressure on the button module.

2. The button module of claim 1, wherein
the pressure sensor layer includes a plurality of resistance elements, and detects pressure according to a resistance change by using the plurality of resistance elements.

3. The button module of claim 2, wherein
the pressure sensor layer is deposed at a lower portion of the bracket,
the bracket includes a plurality of protrusions that come into contact with the pressure sensor layer, and
a protrusion adjacent to a position where the external pressure is generated among the plurality of protrusions causes a change in pressure to the pressure sensor layer, depending on positions where the external pressure is generated.

4. The button module of claim 2, wherein
the pressure sensor layer is deposed between the first adhesive layer and the electrode substrate, and
a change in density of an elastic body included in the first adhesive layer causes a change in pressure to the pressure sensor layer.

5. The button module of claim 1, wherein
the second electrode layer includes a plurality of electrodes arranged at a constant interval.

6. The button module of claim 1, wherein
the button housing is electrically connected to the second electrode layer and transfers the external pressure to the second electrode layer.

7. An electronic device comprising:
a display;
a button module;
a main board electrically connected to the button module;
at least one processor; and
a memory electrically connected to the at least one processor and storing at least one code executed by the at least one processor,
wherein the button module comprises an electrode substrate, a bracket deposed on a lower surface of the electrode substrate, a first adhesive layer deposed on the electrode substrate, a first electrode layer deposed on the first adhesive layer, a second adhesive layer deposed on the first electrode layer, a second electrode layer deposed on the second adhesive layer, a button housing configured to surround the electrode substrate, the first adhesive layer, the first electrode layer, the second adhesive layer, and the second electrode layer, and a pressure sensor layer configured to detect a type of pressure that changes according to an external pressure on the button module,
the bracket includes a plurality of protrusions that come into contact with the pressure sensor layer,
a protrusion adjacent to a position where the external pressure is generated among the plurality of protrusions causes a change in pressure to the pressure sensor layer, depending on positions where the external pressure is generated,
the main board includes a haptic motor configured to provide haptic feedback according to pressure detected by the pressure sensor layer, and
the memory stores code that causes the at least one processor to determine a type of external pressure detected by the pressure sensor layer.

8. The electronic device of claim 7, wherein
the pressure sensor layer includes a plurality of resistance elements, and detects pressure according to a resistance change by using the plurality of resistance elements.

9. The electronic device of claim 8, wherein
the pressure sensor layer is deposed at a lower portion of the bracket, and
the memory stores code that causes the at least one processor to measure a change in pressure, which is generated by a protrusion adjacent to a position where the external pressure is generated among the plurality of protrusions, to the pressure sensor layer, depending on positions where the external pressure is generated.

10. The electronic device of claim 8, wherein
the pressure sensor layer is deposed between the first adhesive layer and the electrode substrate,
a change in density of an elastic body included in the first adhesive layer causes a change in pressure to the pressure sensor layer, and
code is stored which causes a change in density of an elastic body included in the first adhesive layer to measure a change in pressure to the pressure sensor layer.

11. The electronic device of claim 7, wherein
the memory stores code that causes the at least one processor to provide haptic feedback to the electronic device through the haptic motor according to the change in pressure.

12. The electronic device of claim 7, wherein
the memory stores code that causes the at least one processor to measure a change in capacitance generated between the first electrode layer and the second electrode layer.

13. The electronic device of claim 12, wherein
the memory stores code that causes the at least one processor to perform a content selection function, a scroll movement function, a screen switching function, a zoom-in function, or a zoom-out function according to a type of pressure change detected by the pressure sensor layer or a change in the capacitance.

14. An operating method of an electronic device including a button module having multiple functions, the operating method comprising:
detecting an external pressure or a change in capacitance through the button module;
determining a type of the external pressure or the change in the capacitance; and
performing at least one operation among app content selection, scroll movement, screen switching, camera shooting, camera zoom-in, and camera zoom-out based on the type of the external pressure or the change in the capacitance.

15. The operating method of claim 14, wherein
the performing of the at least one operation includes providing haptic feedback corresponding to the operation through a haptic motor.

16. The operating method of claim 14, wherein
the performing of the at least one operation includes performing any one operation among the app content selection, the scroll movement, and the screen switching when the external pressure moves from a top to a bottom of the button module or when the external pressure moves from the bottom to the top of the button module.

17. The operating method of claim 14, wherein the performing of the at least one operation comprises:
performing a first operation when the external pressure or the change in the capacitance is greater than or equal to a first threshold and less than a second threshold,
performing a second operation that is different from the first operation when the external pressure or the change in the capacitance is less than the first threshold, and
performing a third operation that is different from the first operation and the second operation when the external pressure or the change in the capacitance is greater than or equal to the second threshold and greater than the first threshold.
